(19) United States
(12) Patent Application Publication
(10) Pub. No.: US 2015/0279942 A1
(43) Pub. Date: Oct. 1, 2015

(54) PROCESS TO PRODUCE NITRIDE SEMICONDUCTOR DEVICE

(71) Applicant: SUMITOMO ELECTRIC INDUSTRIES, LTD., Osaka (JP)

(72) Inventors: Keiichi YUI, Yokohama-shi (JP); Ken Nakata, Yokohama-shi (JP); Isao Makabe, Yokohama-shi (JP); Tsuyoshi Kouchi, Yokohama-shi (JP)

(73) Assignee: SUMITOMO ELECTRIC INDUSTRIES, LTD., Osaka (JP)

(21) Appl. No.: 14/660,208

(22) Filed: Mar. 17, 2015

(30) Foreign Application Priority Data
Mar. 28, 2014 (JP) P2014-068299

(51) Int. Cl. H01L 29/20; H01L 29/16; H01L 21/02

(52) U.S. Cl. CPC H01L 29/2003; H01L 21/0254; H01L 21/0262; H01L 29/1608

(57) ABSTRACT

A process to obtain a nitride transistor containing a gallium nitride (GaN) is disclosed. The process first grows an AlN layer on a substrate, then crown the GaN layer cc the AlN layer. Between the growth of the AlN layer and the GaN layer, the process leaves the AlN layer grown art the substrate in a temperature higher than the growth temperature of the AlN layer for a preset period. This heat treatment of the AlN layer sublimates impurities accumulated on the surface of the AlN layer and enhances the crystal quality of the GaN layer grown thereon.

### BACKGROUND OF THE INVENTION

1. Field of the Invention

The present invention relates to a method to produce a nitride semiconductor device.

2. Background Arts

A power semiconductor device has been attracted for fields unable to apply silicon-based semiconductor device. One type of the power semiconductor devices is a high electron mobility transistor (HEMT) made of nitride semiconductor materials typically a gallium nitride (GaN). A HEMT containing GaN often provides, in order to enhance the high frequency performance thereof, an aluminum-gallium-nitride (AlGaN) layer between a substrate made of silicon carbide (SiC) and/or silicon (Si) and a GaN layer operable as a channel layer, Because the AlGaN layer has a lattice constant mismatched with that of the GaN; the GaN channel layer grown on the AlGaN layer sometimes or often causes dislocations to degrade the crystal quality thereof.

One prior art has disclosed a technique to obtain a GaN layer with a superior quality on a Si substrate with a crystal surface offset from the primary surface to match. the lattice constant with that of the GaN layer, and to interpose an aluminum-nitride (AlN) layer between the Si substrate and the GaN layer. The GaN layer operable as the channel layer maybe grown on the AlN layer. However, there could be a room to improve the crystal quality of the GaN layer in addition to use an off-axis Si substrate, in particular, how influence the surface of the AlN layer on the crystal quality of the GaN layer, and how decrease impurities operating as electron traps in the GaN layer.

### SUMMARY OF THE INVENTION

An aspect of the present application relates to a process to produce a nitride semiconductor device. The method comprises steps of (a) growing an aluminum nitride (AlN) layer on a substrate, (b) leaving the AlN layer in the second temperature, and (c) growing a gallium nitride (GaN) layer on the AlN layer at the third temperature. A feature of the process of the present invention is that the second temperature is higher than the first temperature, the third temperature is not lower than 1030° C. but not higher than 1100° C., the gas sources at least for the group III elements are ceased to be supplied during the heat treatment of the AlN layer under the second temperature, and the GaN layer grown on the AlN layer has a thickness t not less than 300 nm and a value given by the equation of:

t[nm]>300+{(d/l)−1.03}*200/0.03,

where d is the sheet resistance of the GaN layer in a dark and l is the sheet resistance thereof in an illumination.

### BRIEF DESCRIPTION OF THE DRAWINGS

The foregoing and other purposes, aspects and advantages will be better understood from the following detailed description of a preferred embodiment of the invention with reference to the drawings, in which

FIG. 1 shows a cross section of a semiconductor device according to an embodiment of the present application;

FIG. 2 is a time chart of the process temperatures and the switching of the source gases;

FIGS. 3A to 3C explain processes to produce the semiconductor device according to an embodiment of the present invention;

FIGS. 4A to 4C explain processes subsequent to that shown in FIG. 3C according to the embodiment of the present invention;

FIGS. 5A to 5C explain processes subsequent to that shown in FIG. 4C according to the embodiment of the present invention;

FIG. 6 shows an example of a pit induced on the surface of the GaN layer;

FIG. 7 is a time chart of the process temperatures and the switching of the source gases according to an example comparable to the present invention;

FIGS. 8A and 8B show behaviors of the impurities induced within the GaN layer grown by the comparable method shown in FIG. 7;

FIG. 9 schematically explains the transient recovery of the drain current often observed in a nitride semiconductor device;

FIG. 10 shows a relation between the recovery ratio Idq/Id_{q}0 of the drain current and the ratio d/l of the sheet resistance of the GaN layer in the dark and that under the illumination;

FIG. 11 shows a relation of FWHM of the X-ray rocking curve for (002) surface of the GaN layer against the thickness of the GaN layer grown by the method comparable to the present invention;

FIG. 12 indicates a region where a preferable GaN layer is obtained by the method comparable to the present invention;

FIG. 13 shows a relation of FWHM of the X-ray rocking curve for (002) surface of the GaN layer against the thickness of the GaN layer grown by the method of the embodiment of the present invention;

FIG. 14 indicates a region where a preferable GaN layer is obtained by the method according to the embodiment of the present invention, where FIG. 14 substitutes the broken line 62 for the broken line 42 appearing in FIG. 13;

FIG. 15 is a time chart of the process temperature and the switching of the source gases according to a modification of the present invention; and

FIG. 16 shows a cross section of a semiconductor device according to still another modification of the present invention.

### DESCRIPTION OF EMBODIMENTS

Next, some preferable embodiments according to the present application will be described as referring to drawings. In the description of the drawings, numerals or symbols same with or similar to each other will refer to elements same with or similar to each other without duplicating explanations.

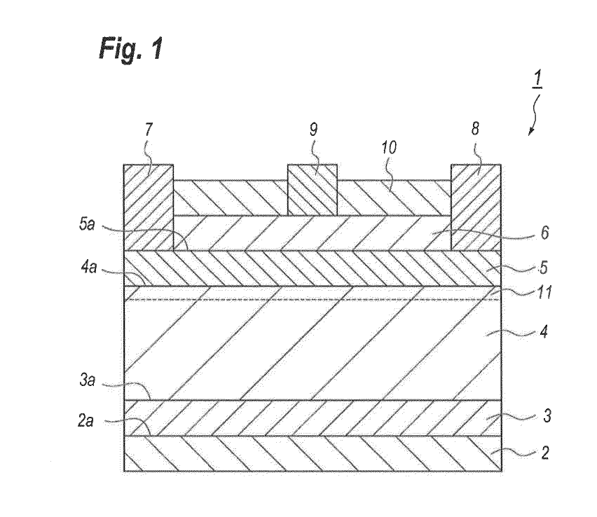

FIG. 1 shows a cross section of a semiconductor device according to an embodiment of the present application. The semiconductor device shown in FIG. 1 provides a substrate 2, an AlN layer 3, a GaN lever 4, an electron supply layer 5, a cap layer 6, source, drain and gate electrodes, 7 to 9, respectively, and a protecting layer 10. The semiconductor device 1 shown in FIG. 1 has a type of the HEMT providing a two-dimensional electron gas (2DEG) in the GaN layer 4 close to the interface between the GaN layer 4 and the electron supply layer 5, which becomes a channel 11 of the semiconductor device 1.

The substrate 2, which is provided for the growth of the semiconductor layers 3 to 6, may be made of silicon (Si) silicon carbide (SiC), sapphire (Al₂O₃), and so on. The present embodiment shown in FIG. 1 provides the substrate made of SiC. The surface 2a of the substrate 2 is preferably smooth but the smoothness or flatness often requested for conventional semiconductor devices is unnecessary.

The AlN layer 3, which is epitaxially grown on the surface 2a of the substrate 2, has a thickness of, for instance, 30 to 200 cm, and operates as a buffer layer for the semiconductor layers grown thereon.

The GaN layer 4, which is epitaxially grown on the surface 3a of the AlN layer 3, has a thickness of 300 to 1400 nm. The GaN layer 4 with the thickness at least 300 nm may effectively suppress the number of pits or dimples appearing in the surface 4a of the GaN layer 4, which restricts the electric performance and the long-term stability of the semiconductor device 1. Also, the GaN layer 4 with the thickness of 1400 nm at most may save the production cost of the semiconductor device 1. The minimum thickness of the GaN layer 4 may be determined by the number of pits formed in the surface 4a thereof. That is, the minimum thickness of the GaN layer 4 is the thickness by which the surface 4a thereof causes the pit density of 10/cm² at most.

The electron supply layer 5, which is epitaxially grown on the surface 4a of the GaN layer 4, has a thickness of 10 to 30 cm. The electron supply layer 5 may be made of undoped AlGaN, or an n-type AlGaN. The cap layer 6, which is epitaxially grown on the surface 5a of the electron supply layer 5, has a thickness of 3 to 10 nm and made of undoped GaN, or n-type GaN.

The source and drain electrodes, 7 and 8, respectively, are provided in regions where the cap layer 5 is removed. The source and drain electrodes, 7 and 8, are directly in contact with the electron supply layer 5. These electrodes, 7 and 8, which are the non-rectifying electrodes, may be stacked metals of titanium (Ti) and aluminum (Al), where the Ti layer is in contact with the electron supply layer 5. The stacked metals may further include another Ti on Al, that is, the stack may have the arrangement of Ti/Al/Ti.

The gate electrode 9 is provided on the cap layer 6 between the source and drain electrodes, 7 and 8. The gate electrode 9 may also have a stacked metal of nickel (Ni) and gold (Au). The gate electrode 9 may be provided on the electron supply layer 5. The protecting layer 10, which may be made of silicon nitride (SiN) covers the cap layer 6.

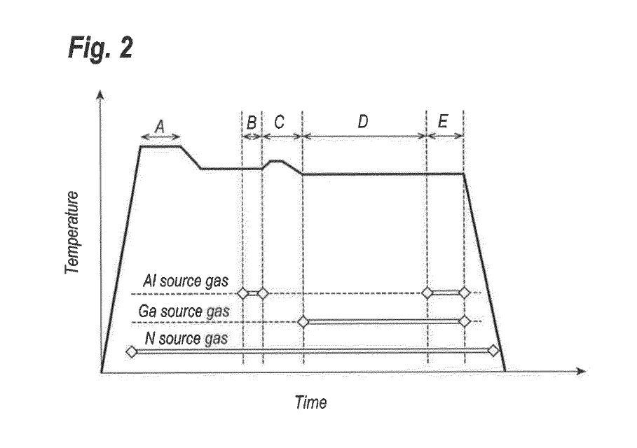

Next, a process to produce the semiconductor device 1 is described as referring to FIGS. 2 to 5. FIG. 2 is a time chart showing process temperatures and the switching of the source gases. The horizontal axis corresponds to the time, while, the vertical axis shows the temperature.

The process first carries out the heat treatment of the substrate 2. Setting the substrate 2 in a process chamber, the temperature in the chamber is raised by a constant rate to a preset temperature and kept in this preset temperature for a period of A as shown in FIG. 2. The preset temperature is, for instance, 1200° C. in the present embodiment. Also, the present embodiment supplies a source gas for nitrogen, which is ammonia (NH₃) during the period A. However, the process may supply no source gases during the period A.

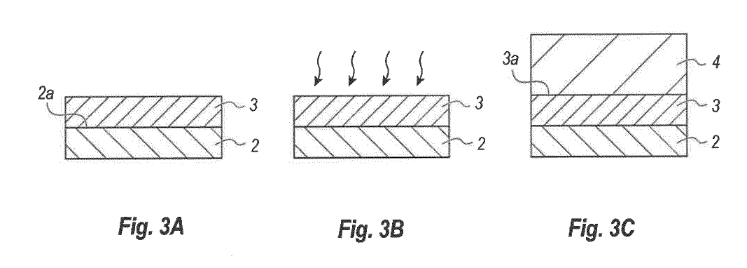

Then, the process grows the AlN layer 3 on the substrate 2 in the first stop during the period 3 as shown in FIGS. 2 and 3A. Supplying the source gases for aluminum (Al) and nitrogen (N), setting the growth temperature of 1080° C. and the growth pressure of 13.3 kPa, the organo-metallic vapor phase epitaxy (OMVPE) technique may grow the AlN layer 3 by a thickness of 50 nm. The present embodiment supplies, tri-methyl-aluminum (TMA) gas as the source gas for Al and ammonia (NH₃) for N. The flow rate of the ammonia is 0.5 mol/min, Although the growth temperature is 1080° C. in the present embodiment, the temperature may be a range from 1030 to 1100° C.

Then, the process carries out the heat treatment for the grown AlN layer 3 in the second step during the period C as shown in FIGS. 2 and 3B. Specifically, ceasing the supply of the source gas for Al but continuing the supply of the source gas for N, and setting a temperature higher than the preset temperature of the period B, the grown AlN layer 3 is left in the chamber in the period C. A feature of the process of the embodiment is that the temperature in the period C is raised from that in the period B. Specifically, the temperature in the period C maybe higher than that in the period B by 40° C. at most, which is a condition to sufficiently sublimate impurities accumulated on the surface 3a of the AlN layer 3. The period where the raised temperature is kept is at least three (3) minutes and five (5) minutes at most. The short limit of 3 minutes is for sublimating the impurities sufficiently, and the long limit of 5 minutes is due to save the process time. The present embodiment sets the conditions of the temperature and the period to be 1120° C. and 5 minutes, respectively.

Then, the process grows the GaN layer 4 on the surface 3a of the AlN layer 3 in the third step during the period D as shown in FIGS. 2 and 3C. Supplying the source gases for gallium and nitrogen, and setting the growth temperature, the growth pressure, and growth rate to be 1080° C., 13.3 kPa, and 0.4 nm/sec, respectively, the OMVPE technique grows the GaN layer 4 by a thickness of 400 nm. The source gas for Ga is tri-methyl-gallium with a flow rate of 120 umol/min and that for N is ammonia with a flow rate of 0.5 mol/min.

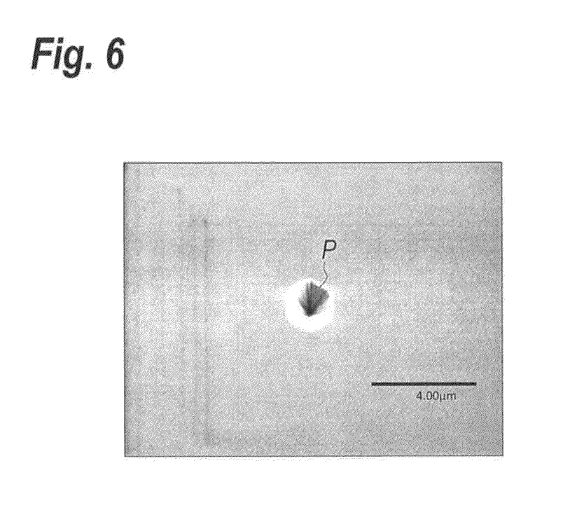

FIG. 6 snows an example of a pit appearing in the surface 4a of the GaN layer 4. The growth temperature of the GaN layer 4 is preferably greater than 1030° C. but lower than 1100° C. The lower limit of the growth temperature is due to suppress the vertical growth of GaN, which means that the generation of the pit shown in FIG. 6 may be effectively suppressed, also the capture of impurities by the growing GaN layer may be also suppressed. On the other hand, the higher limit of the growth temperature is determined by the suppression of the leaking path formed in the interface between the AlN layer 3 and the GaN layer 4, which means that the leak current of the semiconductor device 1 may be effectively reduced. Moreover, the GaN layer 4 preferably has a thickness of 300 to 1400 nm. A GaN layer with thickness greater than 300 nm may suppress the formation of the pit in the surface 4a of the grown GaN layer. On the other hand, a grown GaN layer with a thickness of 1400 nm at most may enhance the productivity of the semiconductor device 1.

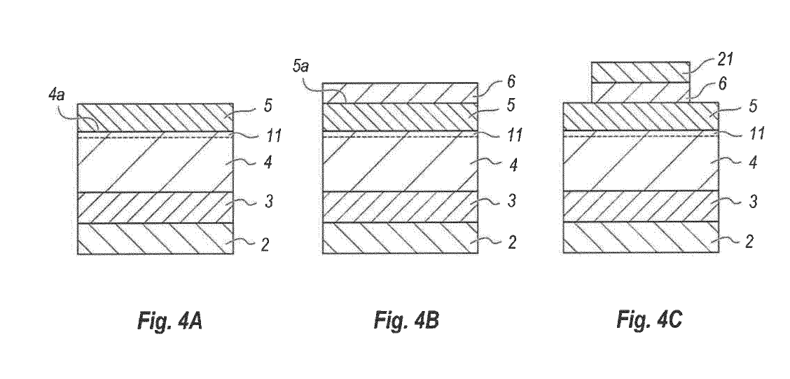

Then, as shown in FIGS. 2 and 4A, the process grows are AlGaN layer on the surface 4a of the GaN layer 4 as an electron supply layer 5 in the fourth step during the period E. Specifically, the OMVPE technique grows the AlGaN layer on the GaN layer 4 by a thickness of 20 nm as supplying the source gases for aluminum (Al), gallium (Ga), and nitrogen (N) at a temperature of 100° C. under a pressure of 13.3 kPa. The electron supply layer 5 forms the two-dimensional electron gas (2DEG) operable as a channel 11 within the GaN layer 4 in a vicinity of the interface against the electron supply layer 5.

Also, as shown in FIGS. 2 and 4B, the OMVPE technique further grows, during the period E as the fifth step, a GaN layer as the cap layer 6 on the electron supply layer 5 by a thickness of 5 nm as supplying the source gases for gallium (Ga) and nitrogen (N) at the temperature of 1080° C. under the pressure of 13.3 kPa.

Next, as shown in FIG. 4C, the process partially removes the cap layer 6 by a patterned photoresist 21 as an etching mask to expose the surface 5a of the electron supply layer 5 in the sixth step. The patterned photoresist 21 may be formed by a conventional photolithography often used in the semiconductor manufacturing process. Areas of the cap layer 6 not covered by the photoresist 21 are etched to expose the surface of the electron supply layer 5.

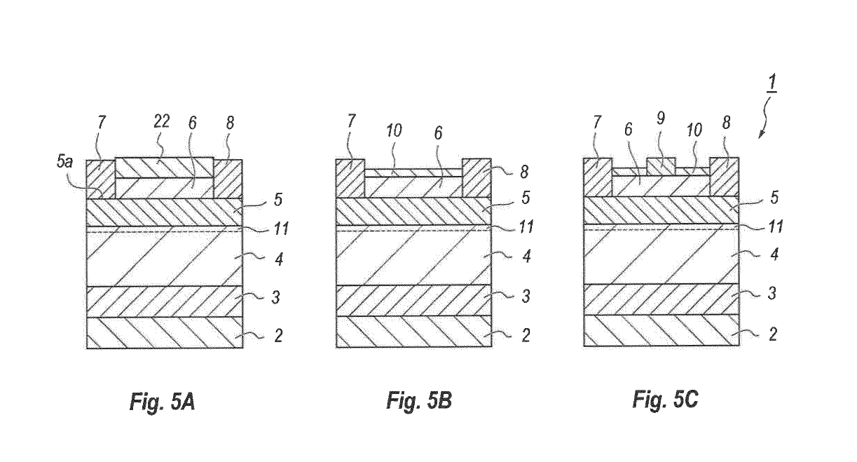

Then, as shown in FIG. 5A, the process forms the source and drain electrodes, 7 and 8, on the exposed surface Bet of the AlGaN layer in the seventh step. The source and drain electrodes, 7 and 8, may be made of stacked metals containing titanium (Ti) and aluminum (Al), where Ti is in contact with the electron supply layer 5. In the present embodiment, the photoresist 21 for etching the cap layer 6 is once removed, then, another photoresist 22 is patterned to form the source and drain electrodes, 7 and 8. Thus, the two-step lithography of the photoresists, 21 and 22, may form the source and drain electrodes, 7 and 8, in respective desirable shapes. The second photoresist 22 is removed after the formation of the source and drain electrodes, 7 and 8. In an alternative, the first photoresist 21 may he left unremoved even after etching the cap layer 6 and used for forming the source and drain electrodes, 7 and 8, which may simplify the manufacturing process.

Next, as shown in FIG. 5B, a protecting layer 10 covers the surface of the cap layer 6 and the source and drain electrodes, 7 and 8, in the eighth step. The protecting layer 10 may be made of silicon nitride (SiN) formed by, for instance, the chemical vapor deposition (CVD) technique. The protecting layer 10 covering the source and drain electrodes, 7 and 8, is partially removed.

Next, the process forms the gate electrode 9 on the cap layer 6 in the ninth step as shown in FIG. 5C. A patterned photoresist is first formed en the protecting layer 10, then, a portion of the protecting layer 10 not covered by the patterned photoresist is etched, and lastly, the gate electrode 9 is formed so as to cover the etched protecting layer 10. The gate electrode 9 may be made of stacked metals of nickel (Ni) and gold (Au), where nickel (Ni) is in contact with the cap layer 6. Thus, the transistor 1 is completed.

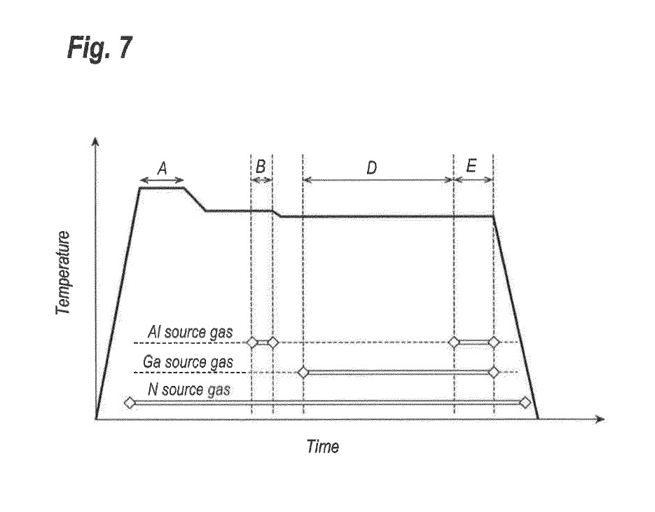

Another process to form a semiconductor device comparable to the present invention will be described. FIG. 7 is a time chart showing conditions for producing a semiconductor device comparable to the present invention. The process shown in FIG. 7 omits the period C between the periods B and C in FIG. 2, that is, the process to perform the thermal treatment of the AlN layer. In this procedure, impurities accumulated on the surface of the AlN layer, where the impurities include dusts, particles, and so on, are taken within the GaN layer. The impurities localize in the interface between the AlN layer and the GaN layer, and show a homogeneous distribution in rest of GaN layers.

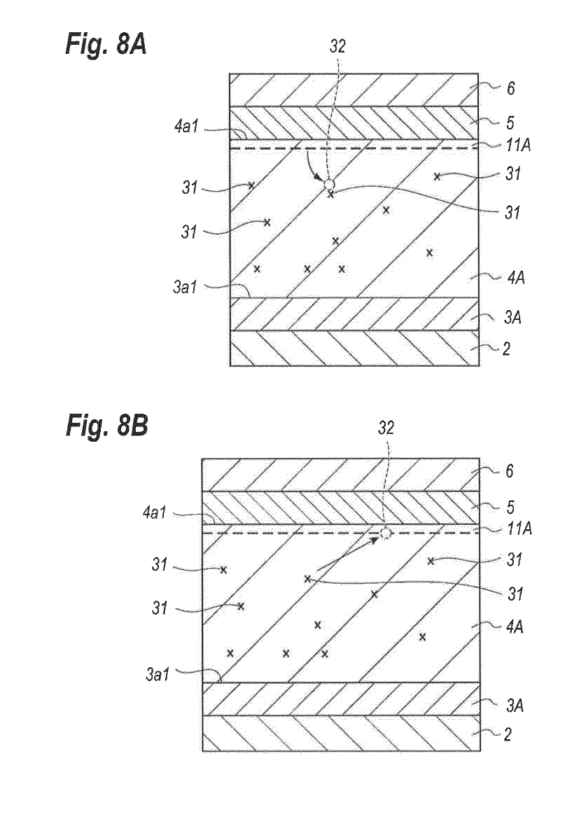

FIGS. 8A and 8B schematically illustrate distributions and behaviors of the impurities in the GaN layer. As shown in FIG. 8A, when electrons flow within the channel 11A formed in a vicinity of the surface 4a1 of the GaN layer 4A, a part of the electrons 32 is captured by the impurity 31 homogeneously distributed in the GaN layer 4A. Thus, the impurity 31 operates as an electron trap. The electrons 32 captured in the impurities 31 are emitted therefrom before long and enter in the channel 11A again. This mechanism of the capture and the emission of the electrons by/from the impurities are called as the transient response of a semiconductor material. When a transistor has the GaN layer 4A showing the transient response, the drain current of the transistor becomes unstable, in particular, the drain current shows an excess decrease after a sudden and extreme increase with a subsequent sudden decrease. The amount of the excess decrease depends on the concentration of the impurities. The GaN layer 4 grown by the procedure of the present invention contains lesser impurities and suppresses the transient response. That is, the transistor 1 shown in FIG. 1 may suppress the excess decrease of the drain current.

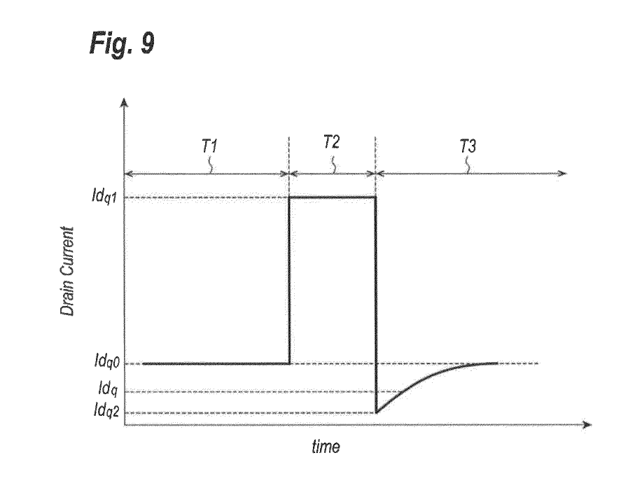

FIG. 9 is a time chart showing the transient response of the drain current of the transistor 1 according to the present invention. The vertical axis shows the drain current and the horizontal axis corresponds to the time. First, the period T1 is an off-state when the drain current Id of the transistor is shown by Id_{q0}. Second, the period T2 is an on-state when the drain current shown by Id_{q1} becomes extremely large compared with that Id_{q0} in the period T1 Third, the period T3 is an off-state again. That is, the transistor 1 is driven in the burst mode. At an instant when the transistor 1 turns to the off-state from the on-state, that is, the beginning of the second of T3, the drain current shows an excess decrease to a level Id_{q2} than the drain current Id_{q0} in the first off-state T1; then, gradually recovers the original drain current. This transient appearing in the drain current may be considered to be due to the transient response described above attributed to the impurities.

Specifically, at the end of the on-state T2, a part of the electrons 32 just flowing in the channel 11 is captured by the impurities 31, which causes the excess decrease of the drain current to the value Id_{q2}, which is less than the original drain current Id_{q0}, at the beginning of the second off-state T3. The impurities 32 gradually release or emit; the captured electrons to the channel 11, which results in the gradual recovery of the drain current. Setting the recovery ratio to be a ratio of the drain current Idq measured one (1) second after the beginning of the second off-state against the original drain current Id_{q0}, the recovery ratio is preferable to be greater than 70% for a transistor practically used in the field.

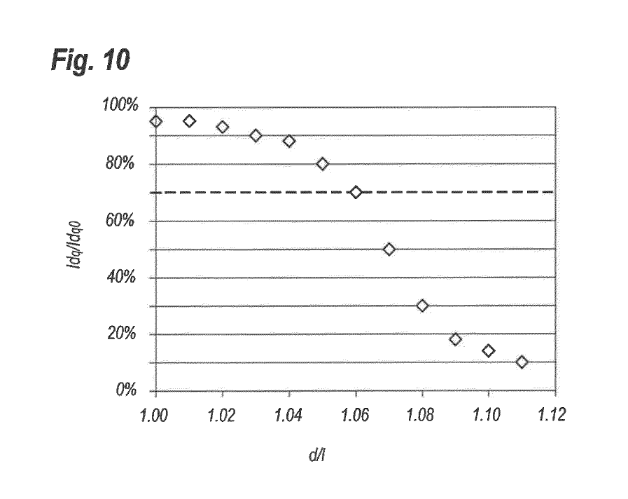

Another evaluation of the GaN layer 4 will be described. FIGS. 10 shows a relation of the recovery ratio against a photosensitivity, where the photosensitivity may be measured by a ratio (d/l) of the sheet resistance d in a dark against the sheet resistance 1 of the GaN layer illuminated with light. In FIG. 10, the vertical axis shows the recovery ratio (Idq/Id_{q0}) and the horizontal axis corresponds to the photosensitivity (d/l) When the transistor 1 shows the transient response described above, the photosensitivity (d/l) becomes large because the light illuminating the GaN layer accelerates the release or the emission of the electrons captured by the impurities, which results in the increase of the conductive electron, hence, the decrease of the sheet resistance. As shown in FIG. 10, a region where the photosensitivity d/l less than 1.06 shows the recovery ratio greater than 70% In the experiment shown in FIG. 10, the sheet resistance of the GaN layer was evaluated by, for instance, the non-contacting eddy current sensor before forming the source, drain, and gate electrodes.

The sheet resistance of the GaN layer 4 is substantially equivalent to the sheet resistance of the 2DEG.

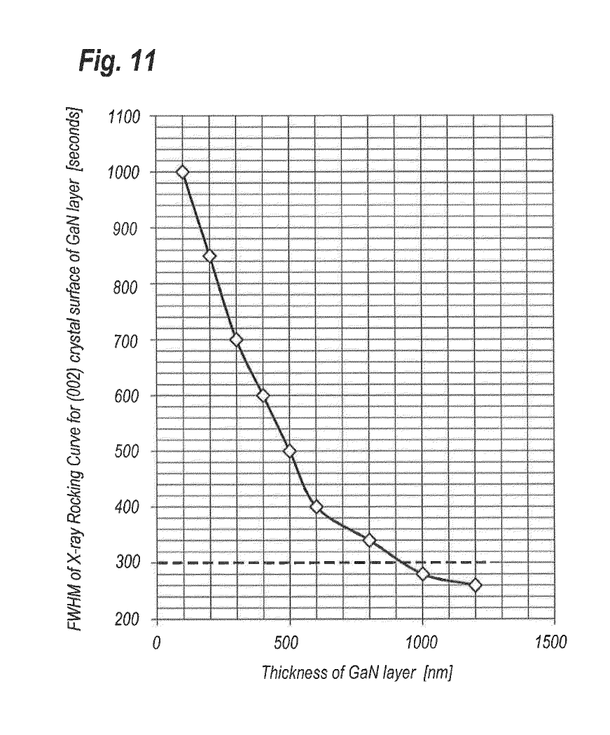

FIG. 11 shows a relation between the crystal quality of the GaN layer 4A grown by the method comparable to the present embodiment against the thickness of the GaN layer 4A shown in FIG. 8. In FIG. 11, the vertical axis corresponds to the full width at half maximum (FWHM) measured by the X-ray rocking curve for the (002) crystal surface of the GaN layer 4A. The FWHM generally becomes one of indices of the dislocations contained in the crystal, and decreases as the thickness of the crystal under consideration becomes larger because the dislocations are terminated as the mother material becomes thicker. That is, as the thickness of the GaN layer 4A becomes large, the FWHM is of the X-ray rocking curve for the (002) crystal surface becomes narrower When a GaN layer is applied to the channel layer of a HEMT, the FWHM of the X-ray rocking curve for the (002) surface of this GaN layer is preferably less than 300 seconds. As shown in FIG. 11, the GaN layer 4 of the comparable example shows the FWHM for the (002) surface less than 300 seconds when the thickness thereof becomes greater than 900 nm.

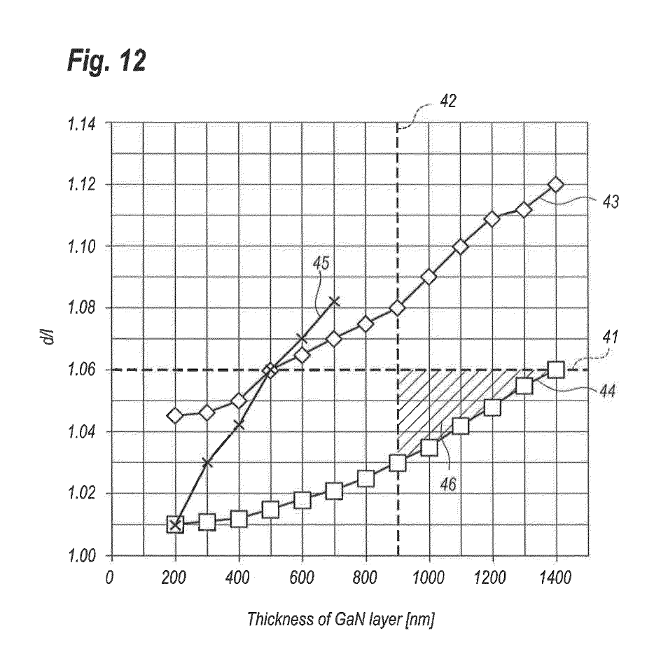

FIG. 12 summarizes the quality of the GaN layer 4A grown by the method shown in FIG. 7, which is comparable to the present invention. In FIG. 12, the vertical axis corresponds to the photosensitivity, namely, the ratio (d/l) of the sheet resistance in the dark against that in the illumination, while, the horizontal axis corresponds to the thickness of the GaN layer 4A. A thick broken line 41 corresponds to the photosensitivity of 106, and another thick broken line 52 corresponds to the thickness of the GaN layer 4A of 900 nm where the FWHM of the X-ray rocking curve for the (002) surface less than 300 seconds. The behavior 43 shows a relation of the photosensitivity (d/l) against the thickness of the GaN layer 4A when the GaN layer 4A is grown at 1030° C., while, the behavior 44 shows the relation same as that described above but when the GaN layer 4A is grown at 1100° C. The behavior 4 shows the relation same with that above explained when the GaN layer 4A shows the surface pit density of 10 cm².

Further explaining FIG. 12, the recovery ratio of the drain current becomes greater than 70% for a GaN entering the area below the broken line 41, that is the area where the ratio d/l is less than 1.06, GaN entering the area right hand side of the second broken line 42 shows the FWHM of the X-ray rocking curve less than 300 seconds Furthermore, a GaN entering the area between two behaviors, 43 and 44, may suppress the leak current due to the interface between the GaN layer and the AlN layer beneath the GaN layer, Lastly, a GaN entering the area right hand side of the behavior 45 shows the surface pit density less than or equal to 10/cm².

The GaN layer applicable to a HEMT device, as described, above, preferably satisfies conditions of:

(1) the growth temperature between 1030 to 1100° C. from the limitation of the leak current;

(2) the ratio d/l of the sheet resistance in the dark against the illumination less than 1.06 from the recovery ratio of the drain current; and

(3) the FWHM of the X-ray rocking curve for the (002) surface less than 300 seconds from the crystal quality.

Accordingly, a GaN layer 4A grown by the method comparable to the present invention entering the hatched region 46 in FIG. 12 is considered to satisfy the conditions above.

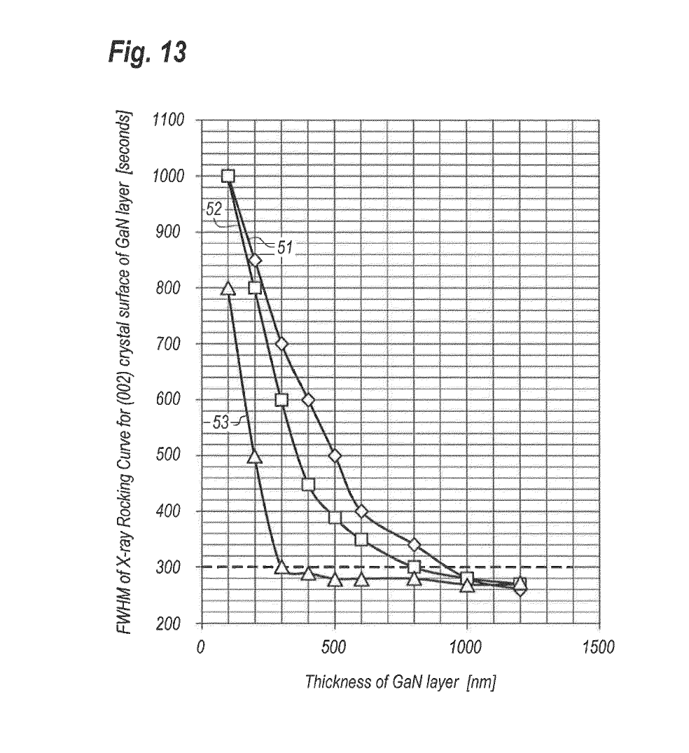

FIG. 13, which may correspond to FIG. 11, shows the relation of the FWHM of the X-ray rocking curve for the (002) surface of a GaN layer 4 grown by the method of the present invention. The behavior 51 copies the behavior shown in FIG. 11, The behavior 32 shows a result when the thermal treatment is carried out under a temperature higher than the growth temperature of the AlN layer 3 by 20° C.; and the behavior 53 shows a result when the thermal treatment is done at a temperature higher than that of the AlN layer 3 by 40° C. For the behavior 52, the GaN layer with a thickness greater than 800 nm shows the FWHM less than 300 seconds, but, for the behavior 53, a GaN layer with a thickness less than 300 nm shows the FWHM less than 300 seconds. This means that the thermal treatment of the AlN layer at the temperature 40° C. higher than the growth temperature of the AlN layer 3 may sublimate impurities accumulated on the surface 3a of the AlN layer 3. Also, the heat treatment for the AlN layer 3 may reconstruct the outermost surface thereof to suppress dangling bonds of aluminum and nitrogen.

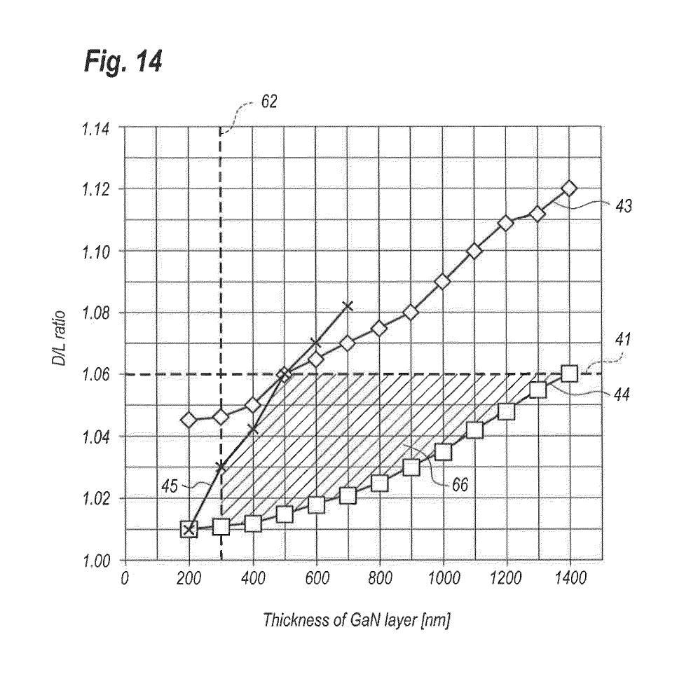

FIG. 14 substitutes the broken line 62 for the broken line 42 appearing in FIG. 12, which corresponds to a GaN showing the FWHM of the X-ray rocking curve for the (002) surface less than 300 seconds. A GaN entering an area in the right hand side of the broken line 62 shows the FWHM of the X-ray rocking curve for the (002) surface less than 300 seconds. Further specifically, a GaN entering an area surrounded by the broken lines, 41 and 62, and behaviors, 43 and 44, has the conditions (1) to (3) above described. Moreover, taking the surface pit density less than or equal to 10/cm²the preferable range for the thickness t of the GaN layer is limited in the right hand side of the behavior 45, which is denoted by:

t[nm]>300+{(d/l)−1.03}*200/0.03,

When such a GaN layer is applied to the HENT device shown in FIG. 1, the HEMT device may show an excellent performance and a distinguishable long-term stability.

Next, advantages of he method for manufacturing a semiconductor device according to the present invention will be described. As already described, the method of the present invention interposes a process to leave the grown AlN layer 3 in a temperature higher than the growth temperature of the AlN layer for a preset period. The interposed process may sublimate the impurities accumulated on the surface 3a of the AlN layer 3 and reduce the impurity concentration and the dislocations to be taken within the GaN layer 4 grown on the AlN layer 3. Even the thickness of the GaN layer 4 is thinner than 1400 nm, the semiconductor device providing thus grown GaN layer 4 shows an excellent performance. Also, such a GaN layer 4 shows the ratio of the sheet resistance d in the dark against that l under the illumination, namely d/l, smaller than 1.06, and the device providing such GaN layer 4 shows the decreased transient phenomenon of the drain current.

The temperature under which the grown AlN layer 3 is left may be higher than the growth temperature of the AlN layer 3 by 20 to 40° C. The preset period of the heat treatment for the AlN layer 3 may be longer than three (3) minutes but shorter than five (5) minutes to sublimate the impurities accumulated on the surface of the AlN layer thoroughly.

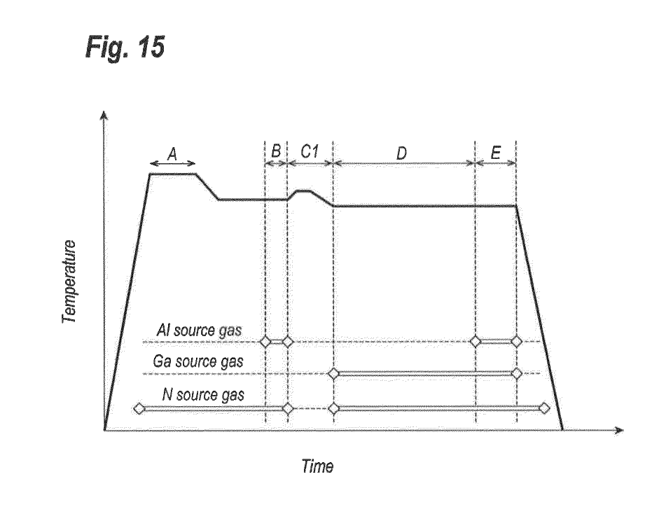

FIG. 15 shows a time chart of the growth of the semiconductor layers modified from that shown in FIG. 2. The modified process shown in FIG. 15 ceases the supply of the source gas for nitrogen (N) in addition to the source gases for the group III elements during the period Cl. Even when the source gas for nitrogen (N) is ceased, the sublimation of the impurities on the surface of the AlN layer 3 may be securely performed. In particular, as already is described, the process requires to supply ammonia (NH₃) as the source gas for the group V elements by a rate far greater than that of the source gases for the group III elements. Accordingly, the modified process to cease the supply of the ammonia as the source gas for the group V element shows an advantage in a viewpoint of saving the source gases.

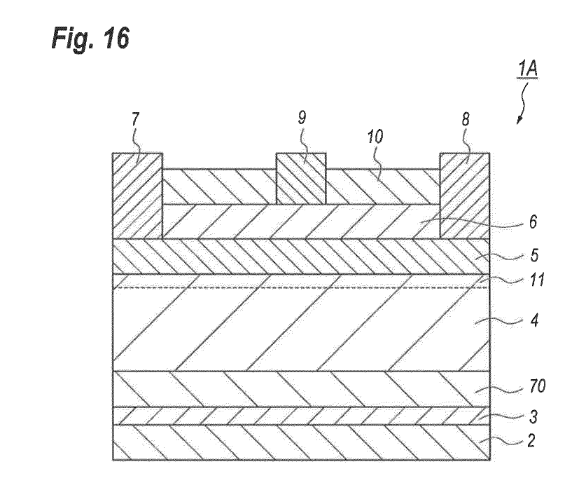

FIG. 16 shows a cross section of a transistor according to still another modification of the present invention, The transistor 1A provides an AlGaN layer 70 between the AlN layer 3 and the GaN layer 4. Three layers of the AlN layer 3 and the AlGaN layer 70 operate as a buffer layer. Because the AlGaN layer 70 has bandgap energy greater than that of the GaN layer 4, the bandgap energy of the buffer layer is totally raised from the level where the buffer layer is constituted only by the AlN layer 3, in particular, the conduction level of the buffer layer may be raised. The buffer layer having a raised conduction band may suppress the short channel effect; accordingly, the transistor 1A may provide a shorter gate length to enhance the high frequency performance thereof.

While particular embodiments of the present invention have been described herein for purposes of illustration, many modifications and changes will become apparent. to those skilled in the art. For instance, the AlN layer may be grown on the substrate by conditions modified from those described above. Also, the cap layer 6 provided on the electron supply layer is not always necessary. Accordingly, the appended claims are intended to encompass all such modifications and changes as fall within the true spirit and scope of this invention.

What is claimed is

1. A process to produce a nitride semiconductor device, comprising steps of:
(a) growing an aluminum nitride (AlN) layer on a substrate at a first temperature as supplying source gases for aluminum (Al) and nitrogen (N);
(b) leaving the AlN layer under a second temperature higher than the first temperature as ceasing a supply of one of the source gases for the aluminum (Al); and
(c) growing a gallium nitride (GaN) layer at a third temperature not lower than 1030° C. but not higher than 1100° C.
wherein, denoting sheet resistance of the GaN layer is under illumination and the sheet resistance in dark are l and d, respectively, the GaN layer has a ratio d/l less than 1.06, and a thickness t not less than 300 nm and a value given by an equation of:
t[nm]>300+{(d/l)−1.03}*200/0.03,

2. The method of claim 1
wherein the step (b) includes a step of setting the second temperature being higher than the first temperature by 20 to 40° C.

3. The method of claim 1,
wherein the step (b) includes a step of holding the AlN layer in the second temperature for 3 to 5 minutes.

4. The method of claim 1,
wherein the step (b) includes a step of ceasing the supply of another source gas for the nitrogen (N).

5. The method of claim 1,
wherein the step (b) includes a step of supplying another source gas for the nitrogen (N).

6. The method of claim 1,
further comprising a step of, before the stop (a), holding the substrate in a temperature higher than the first temperature.

7. The method of claim 6
further comprising a step of, before the step (a) but after the step of holding the substrate in the temperature higher than the first temperature, holding the substrate in the first temperature as supplying a source gas only for the nitrogen (N).

8. The method of claim 1,
wherein the step (c) includes a step of setting the third temperature same with the first temperature.

9. The method of claim 1,
wherein the step (c) includes a step of setting the third temperature lower than the first temperature.

10. A semiconductor device, comprising:
a substrate;
an aluminum nitride (AlN) layer provided on the substrate, the AlN layer having a thickness of 30 to 200 mm; and
a gallium nitride (GaN) layer provided on the AlN layer, the GaN layer having a thickness of 300 to 1400 nm,
wherein the GaN layer has a ratio of sheet resistance under illumination and the sheet resistance in dark smaller than 1.06 and pit density in a top surface thereof less than or equal to 10/cm².

11. The semiconductor device of claim 10,
further comprising,
an electron supplying layer provided on the GaN layer, the electron supplying layer being made of AlGaN and. having a thickness of 10 to 30 nm, and
a cap layer provided. on the electron. supplying layer, the cap layer being made of GaN and having a thickness of 3 to 10 nm.

12. The semiconductor device of claim 11,
wherein the electron supplying layer is an n-type.

13. The semiconductor device of claim 11,
wherein the cap layer is an n-type. 14, The semiconductor device of claim 10,
wherein the substrate is one of silicon (Si), silicon carbide (SiC), and sapphire.
